(19) United States
(12) Patent Application Publication
(10) Pub. No.: US 2014/0321080 A1
(43) Pub. Date: Oct. 30, 2014

(54) ELECTRICAL SOCKET

(71) Applicant: INTERNATIONAL BUSINESS MACHINES CORPORATION, ARMONK, NY (US)

(72) Inventors: Colin I. Holyoake, Hursley (GB); James S. Taylor, Hursley (GB)

(73) Assignee: INTERNATIONAL BUSINESS MACHINES CORPORATION, ARMONK, NY (US)

(21) Appl. No.: 14/219,258

(22) Filed: Mar. 19, 2014

(30) Foreign Application Priority Data
Apr. 24, 2013 (GB) 1307346.5

(51) Int. Cl. H01R 13/04; H05K 1/11

(52) U.S. Cl. CPC H01R 13/04; H05K 1/117
USPC 361/752; 439/11

(57) ABSTRACT

An electrical socket comprises a body. A sleeve having a longitudinal axis is mounted in the body for receiving an electrical plug. At least one electrical contact is located in the sleeve for completing an electrical connection with a corresponding electrical contact of the plug when inserted in the sleeve. The sleeve is mounted to pivot about a point on the longitudinal axis thereof for movement relative to the body in response to a force applied to the sleeve in a direction lateral to the longitudinal axis of the sleeve.

This application is a counterpart of and claims the benefit of priority to United Kingdom Patent Office Application Serial No. GB 1307346.5, filed on Apr. 24, 2013, the contents of which are hereby incorporated by reference.

### BACKGROUND

1. Field

The present invention generally relates to electrical sockets and particularly relates to electrical sockets for portable devices.

2. Description of the Related Art

Portable electronic and electrical devices, such as notebook computers, tablets, and mobile telephones, typically have one or more electrical sockets to receive electrical plugs for establishing electrical cable connections to external devices and electrical power sources. For example, many such conventional devices include a socket for receiving a coaxial power connector, such as an Electronic Industries Association of Japan (EIAJ) type EIAJ RC-5320A connector. This form of connector is a two contact connector in which one contact is provided by an outer sleeve and the other contact is provided by an inner barrel coaxial with and insulated from the outer sleeve. An insulator ring is provided at the tip of the sleeve. A circumferential groove is provided in the sleeve adjacent the tip. In operation, the connector is pushed into a recipient power socket in a device to be powered. The socket typically comprises a formation configured to engage with the groove and/or ring on the connector to provide a level of retention of the connector within the socket, at least by interference fit. The socket typically has a set of contact pins extending therefrom. The contact pins are typically soldered into a printed circuit board within the host device to secure the socket within the device and provide electrical connection to circuitry within the device. To disengage the connector from the socket, a user pulls the body of the connector away from and along the longitudinal axis of the socket.

A problem with this arrangement is that damage can be imparted to the device when it is inadvertently moved with the power connector plugged into the socket. In that situation, forces may be applied to the connector that are not solely along the longitudinal axis of the socket. Such forces do not then cause the connector to release from the socket. This can introduce excess tensile stress within the cable connected to the device via the connector. Such stress can produce breakages within the conductors in the cable. Equally, where the connector fails to release and the cable is pulled at an angle relative to the device, excess sheer and torsional stresses can be introduced in the connector and at the junction between the socket and printed circuit board. If the connector and/or socket are made of relatively brittle material, such stresses can damage to such components to the extent that either or both require replacement. Clearly, the risk of such damage can be reduced by manufacturing the connector and/or socket from a relatively tough material. That said, typically, the printed circuit board on which socket is mounted is relatively brittle, and therefore susceptible to damage from torsional and/or shear stresses imparted through the socket, irrespective of the choice of socket material.

It would be desirable to provide a socket that reduces the risk of damage to a portable device when it is moved with cabling left inadvertently connected.

### SUMMARY

In an embodiment of the present invention, there is provided an electrical socket comprising a body, a sleeve mounted in the body for receiving an electrical plug, the sleeve having a longitudinal axis and at least one electrical contact located in the sleeve for completing an electrical connection with a corresponding electrical contact of the plug when inserted in the sleeve. The sleeve is mounted to pivot about a point on the longitudinal axis thereof for movement relative to the body in response to a force applied to the sleeve in a direction lateral to the longitudinal axis of the sleeve against a bias acting on the sleeve and the body and oriented to urge the sleeve towards an equilibrium position relative to the body in the absence of said force.

In an embodiment, the sleeve is mounted to pivot about a point on the longitudinal axis thereof for movement relative to the body in response to a force applied to the sleeve in a direction lateral to the longitudinal axis of the sleeve against a bias acting on the sleeve and the body and oriented to urge the sleeve towards an equilibrium position relative to the body in the absence of said force.

In another embodiment, the sleeve may be universally pivotable about said point. In an embodiment of the invention, the sleeve is in the form of a bore passing through a ball. The body comprises formations for supporting the ball within the body for rotation relative to the body. The bias comprises a spring member connected to the body and to the ball. Alternatively, the bias comprises a first magnet located in the body and a second magnet located in the ball.

Alternatively, the sleeve is pivotable about an axis of rotation passing through the point and oriented orthogonally to the longitudinal axis of the sleeve. In another embodiment of the invention, the sleeve is in the form of a bore extending between diametrically opposed points on a circumferential edge of a disc. The disc and the body comprise complementary formations for supporting the disc within the body for rotation about the axis of rotation. The bias comprises a spring member connected to the body and to the disc. Alternatively, the bias comprises a first magnet located in the body and a second magnet located in the disc.

In an embodiment of the invention, the socket comprises an aperture in a front face of the body exposing an open end of the sleeve for receipt of the plug and limiting movement of the sleeve when the plug inserted therein. When the sleeve is formed in a ball, a portion of the ball protrudes from the front face of the body through the aperture. When the sleeve is formed in a disc, a portion of the disc protrudes from the front face of the body through the aperture.

The front face of the body comprises a flanged rim surrounding the aperture. The flanged rim is threaded for mounting the socket on a panel. In an embodiment of the invention the body is of clam shell construction.

In an embodiment of the invention each contact is connected via a flexible conductor to a corresponding terminal extending outwardly from the body. In another embodiment of the invention each conductor may extend from a base of the body for connecting the socket to a printed circuit board.

In further embodiment of the present invention the embodiment extends to a printed circuit board comprising a plurality of electrical components including a socket as hereinbefore described.

In another embodiment of the present invention the embodiment further extends to a portable electronic device comprising a housing, electronic circuitry located within the housing, and a socket as hereinbefore described located within the housing and connected to the electronic circuitry for facilitating connection of the electronic device to an external electrical signal source via insertion of a plug. The external signal source is an electrical power source and the socket is a power inlet socket connected power supply components of the electrical circuitry. Equally, the external signal source is an input signal source and the socket is a signal input socket connected to signal processing components of the electrical circuitry.

### BRIEF DESCRIPTION OF THE DRAWINGS

The subject matter regarded as the invention is particularly pointed out and distinctly claimed in the concluding portion of the specification. The invention, both as to organization and method of operation, together with objects, features, and advantages thereof, may best be understood by reference to the following detailed description when read with the accompanying drawings.

Preferred embodiments of the present invention will now be described, by way of example only, with the reference to the accompanying drawing, in which:

FIG. 1 is a front view of an electrical socket embodying the present invention;

FIG. 2 is a cross-sectional side view of the electrical socket shown in FIG. 1;

FIG. 3 is a front view of another electrical socket embodying the present invention;

FIG. 4 is a cross-sectional side view of the electrical socket shown in FIG. 3;

FIG. 5 is a plan view of printed circuit board comprising an electrical socket embodying the present invention;

FIG. 6, is an isometric view of a portable electronic device comprising an electrical socket embodying the present invention; and

FIG. 7 is a front view of a musical instrument amplifier comprising an electrical socket embodying the present invention.

### DETAILED DESCRIPTION

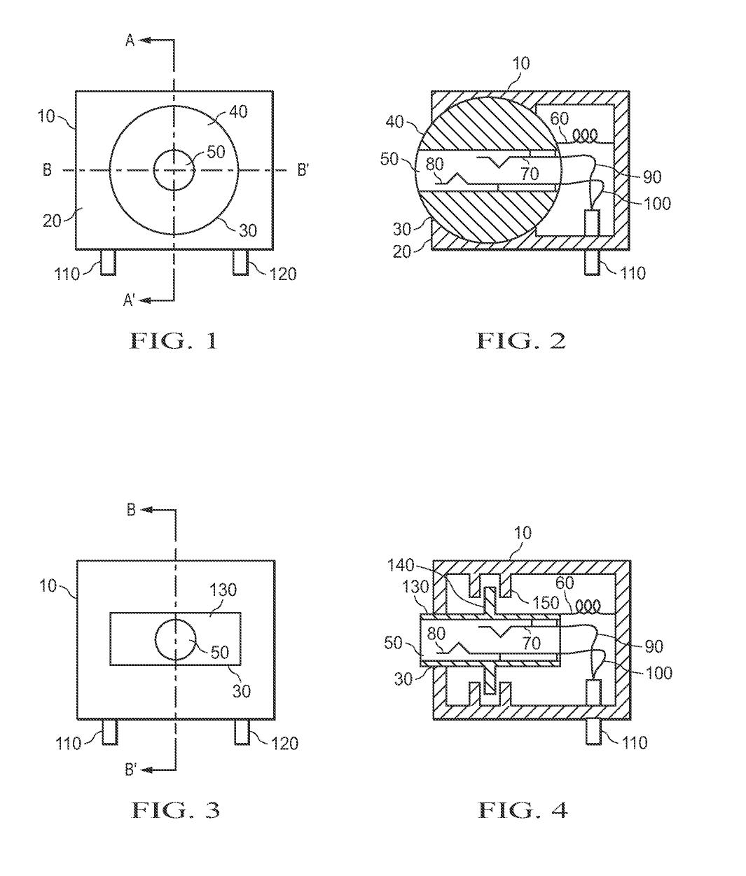

Referring to FIG. 1, an example of an electrical socket embodying the present invention comprises a body 10 having a front face 20. A circular aperture 30 is formed in the front face 20. A ball 40 is rotatably mounted in the body 10. A portion of the ball 40 protrudes from the front face 20 of the body 10 through the aperture 30. A cylindrical bore 50, open at each end, passes through the centre of the ball 40. The bore 50 provides a sleeve having a longitudinal axis along which a plug can be inserted as will be described shortly. The rotational mounting of the ball 40 enables the bore 50 or sleeve to pivot about a point on its longitudinal axis relative to the body 10.

Referring to FIG. 2, there is shown a cross sectional view of the socket of FIG. 1 in the plane A-A′ when viewed in the direction of the arrows. A bias 60 exerts an orientation force on the ball 40 such that, in equilibrium, an open end of the bore 50 is centrally located within the aperture 30. In some embodiments of the present invention, the bias 60 may be provided by a spring connected at one end to the ball 40 and at the other end to the body 10 such that the when the ball is rotated, the spring is elastically extended. In other embodiments of the present invention, the bias 60 may be implemented magnetically, by locating a first permanent magnet in the body 10 and a second permanent magnet in the ball 40, with opposite poles of the first and second permanent magnets facing each other such that an attractive magnetic force causes an open end of the bore 50 to centre in the aperture 30 in equilibrium. It will be appreciated that these implementations of bias 60 are provided by way of illustration only, and that other implementations may be possible.

First and second cantilever spring form contacts 70 and 80 are peripherally mounted within the bore 50 towards the open end of the bore 50 remote from the aperture 30. Each of the first and second contacts 70 and 80 is secured to the bore 50 towards the open end of the bore 50 remote from the aperture 30. Each of the first and second contacts 70 and 80 has an inwardly facing V shaped formation at its end. The V shaped formations are offset relative to each other along the length of bore 50 to engage with different terminals of a two terminal jack plug when inserted into the bore 50.

The first electrical contact 70 is electrically connected to a first terminal or contact pin 110 via a first flexible conductor or lead 100. The second electrical contact 80 is connected to a second terminal or contact pin 120 via a second flexible conductor or lead 90. The first and second contact pins 110 and 120 are secured to, and pass from the interior to the exterior of, the body 10, protruding from the base 10 thereof. The portions of the pins 110 and 120 protruding from the base of the body 10 facilitate the mounting of the socket on a printed circuit board. Specifically, to mount the socket on such a printed circuit board, the pins 110 and 120 are inserted into through vias in the printed circuit board and soldered to solder pads on the back face thereof. Other examples of sockets embodying the present invention may have different fastening means. For example, some such sockets may be alternatively or additionally adapted for fastening to a control panel, such as for example, the control panel of a musical instrument amplifier. In those sockets, the body 10 may be substantially cylindrical in form having a radial flanged portion at some point along its length, with the front face 20 of the body 10 being circular, and the outer surface of the body 10 between the front face 20 and the flanged portion being threaded. Such a socket is secured to panel by inserting the body 10, front face 20 first, into a hole in the panel, sized to receive body 10 from a circuitry side of the panel but only to the point at which the flanged portion abuts the periphery of the hole. A collar having an internal thread matching that of the body 10 is then screwed onto the thread of body 10 from the control side to secure the body 10 in place.

The body 10 may be conveniently be of clam shell construction formed in an upper half and a lower half connected together by a flexible web at the face of the body 10 remote from the front face 20. The two halves and web may be formed as a unitary moulding of plastics material. To assemble the body 10, the unitary moulding is folded at the flexible web to bring the upper and lower halves together at line B-B′ in FIG. 1.

To assemble the socket, a subassembly comprising the ball 40 carrying the first and second contacts 70 and 80 therein and the first and second contact pins 110 and 120 connected to the first and second contacts 70 and 80 via the first and second leads 100 and 90 is produced initially. The ball is then placed in the lower half of the body 10. The first and second pins 110 and 120 are then pressed through receiving vias formed in the base of the lower half of the body 10. The bias 60 is coupled to the ball 40 and the body 10. The upper and lower halves of the body 10 are then closed together. Complementary snap fit formations may be provided on the upper and lower halves of the body 10 to secure them in contact with one another along line B-B′. Alternatively, the upper and lower halves of the body 10 may be glued or fused together along line B-B′.

In operation, a conventional jack plug of the kind having a necked contact at its end is inserted into the bore 50 until the necked contact engages with the V shaped formation of the first contact 70, which is the one of the first and second contacts 70 and 80 closest to the end of the bore 50 remote from the aperture 30. Typically, the jack plug, when so inserted, will connect an electrical lead to circuitry to which the socket 10 is connected. It will be appreciated that the bore 50 acts as a sleeve for receiving the plug.

Normal removal of the jack plug involves a user pulling the body of the jack plug away from the socket along the longitudinal axis of the bore 50 to overcome initial resistance presented by engagement of the V shaped formation at the end of the first contact 16 in the necked portion of jack plug and to subsequently withdraw the jack plug from bore 50. This is preferably achieved while the ball 40 is in equilibrium within the body 10. In the event that a lateral force is instead applied to the jack plug, by, for example, the lead or the jack plug being accidently or carelessly tugged at an angle to the longitudinal axis of the bore 50, the ball 40 swivels within the body 10 in response to and in the direction of the lateral force, thereby pivoting the longitudinal axis of the bore 50 closer to alignment with direction of the tugging force. By pivoting the longitudinal axis of the bore 50 closer to alignment with the tugging force, more of the tugging force is directed to releasing the jack plug from the first and second contacts 70 and 80, less shear and torsional stresses are applied to jack plug, the socket, and circuitry and hardware to which the socket is mechanically connected, and less tensile stress is applied to the lead and the jack plug. Upon relief of the lateral force, the bias 60 returns the ball 40 to its equilibrium position.

In brief summary, the bore 50 is mounted to pivot about a point on the longitudinal axis thereof for movement relative to the body 10 in response to a force applied to the bore 50 in a direction lateral to the longitudinal axis of the bore 50 against the bias 60 acting on the bore 50 and the body 10 and oriented to urge the bore 50 towards the equilibrium position relative to the body 10 in the absence of said force. The ball mounting of the bore 50 leaves the bore 50 universally pivotable about the aforesaid point on its longitudinal axis.

It will be appreciated that the embodiment of the present invention hereinbefore described with reference to FIG. 1 and FIG. 2 at least partially accommodates for a lateral force applied to the jack plug in any direction normal to the longitudinal axis of the bore 50 when the ball 40 is in its equilibrium position.

Referring now to FIG. 3, in a modification to the embodiment of the present invention hereinbefore described with reference to FIG. 1 and FIG. 2, the ball 40 is replaced by a disc 130. The volume of the disc 130 is defined by first and second parallel circular faces connected by circumferential edge or rim. The bore 50 passes through the centre of the disc 130 to open at diametrically opposed points on the rim. The aperture 30 is rectangular to reveal a portion of the rim. Each face has at its centre an outwardly extending spindle 140. Each spindle 140 is engaged within a corresponding collar formation 150 in the body 10. The disc 130 is thereby mounted for rotation within the body 10 about an axis which passes through centre of disc 130 and each spindle 140. The bias 60 acts on the disc 140 to position the opening to the bore 50 for receiving the jack plug centrally within the aperture 30 when in equilibrium. The bore 50 is therefore pivotable about an axis of rotation passing through a point on, and oriented orthogonally to, the longitudinal axis of the bore 50. The spindles 140 and collars 150 provide complementary formations for supporting the disc 130 within the body 10 for rotation about said axis of rotation.

Normal removal of the jack plug, as hereinbefore explained, is preferably achieved here while the disc 130 is in equilibrium within the body 10. In the event that a lateral force is instead applied to the jack plug in a direction parallel to the plane described by either face of the disc 130, by, for example, the lead or the jack plug being accidently or carelessly tugged at an angle to the longitudinal axis of the bore 50, the disc 130 swivels within the body 10 in response to and in the direction of the lateral force, thereby moving the longitudinal axis of the bore 50 closer to alignment with direction of the tugging force. Again, by moving the longitudinal axis of the bore 50 closer to alignment with the tugging force, more of the tugging force is directed to releasing the jack plug from the first and second contacts 70 and 80, less shear and torsional stresses are applied to jack plug, the socket, and circuitry and hardware to which the socket is mechanically connected, and less tensile stress is applied to the lead and the jack plug. Upon relief of the lateral force, the bias 60 returns the disc 130 to its equilibrium position. It will be appreciated however that the embodiment of the present invention hereinbefore described with reference to FIG. 3 and FIG. 4 cannot similarly react to lateral forces applied to the jack plug that are not in a direction parallel to the plane described by either face of the disc 130. In this regard, the embodiment of the present invention hereinbefore described with reference to FIG. 1 and FIG. 2 is typically superior in performance.

It will be appreciated that the embodiment of the present invention hereinbefore with reference to FIG. 3 and FIG. 4 may be assembled in a similar fashion to the embodiment of the present invention hereinbefore described with reference to FIG. 1 and FIG. 2.

Preferred embodiments of the present invention have been hereinbefore described with reference to a jack plug. It will be appreciated however that the present invention is not limited in application to jack plugs alone and that other embodiments of the present invention may be applicable to other forms of plug connector. It will also be appreciated, that, in some embodiments of the present invention, the bias 60 may be omitted.

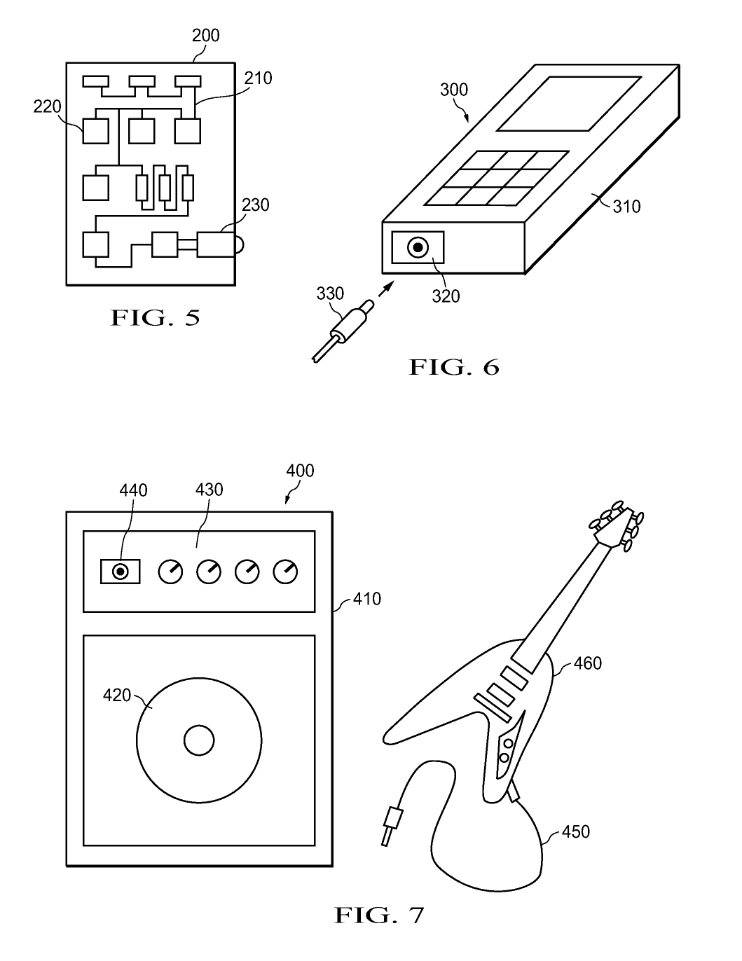

Referring to FIG. 5, an example of a printed circuit board embodying the present invention comprises a printed circuit board or card 200 on which is deposited a plurality of solder pads (not shown). The solder pads are interconnected by a plurality of conductive tracks 210 deposited on the printed circuit board. A plurality of electrical components 220 are soldered to the solder pads. The electrical components include an electrical socket 230 as hereinbefore described with reference to FIG. 1 to FIG. 4. The electrical socket is located at or near an edge of the printed circuit board to facilitate convenient insertion and removal of a plug.

Referring to FIG. 6, as example of a portable electronic device 300 embodying the present invention comprises a housing 310, electronic circuitry (not shown) located within the housing, and an electrical socket 320 as hereinbefore described with reference to FIG. 1 to FIG. 4, located within the housing 310 and connected to the electronic circuitry for facilitating connection of the electronic device to an external electrical signal source, such as an external power supply via insertion of a power supply plug 330. The electrical socket 320 may be mounted on a printed circuit board 200 as hereinbefore described with reference to FIG. 5. It will be appreciated that the portable electronic device may be a notebook computer, tablet, mobile telephony device, digital camera, audio and/or video player or recorder, or other such device.

Referring to FIG. 7, an example of a musical instrument amplifier 400 embodying the present invention comprises a housing 410 containing at least one loudspeaker 420, amplification circuitry (not shown) connected to the loudspeaker 420, and, a control panel 430 connected to the amplification circuitry. A socket 440 as hereinbefore described with reference to FIG. 1 to FIG. 4 is mounted on the control panel 430 for connecting the output of an electrified musical instrument 460 to the input of the amplifier via an instrument lead 450.

1. An electrical socket comprising:
a body;
a sleeve mounted in the body for receiving an electrical plug, wherein the sleeve has a longitudinal axis;
at least one electrical contact located in the sleeve for completing an electrical connection with a corresponding electrical contact of the electrical plug when inserted in the sleeve; and
wherein the sleeve is mounted to pivot about a point on the longitudinal axis thereof for movement relative to the body in response to a force applied to the sleeve in a direction lateral to the longitudinal axis of the sleeve.

2. The socket of claim 1, wherein the sleeve is mounted to pivot about the point on the longitudinal axis thereof for movement relative to the body in response to the force applied to the sleeve in the direction lateral to the longitudinal axis of the sleeve against a bias acting on the sleeve and the body and wherein the bias is oriented to urge the sleeve towards an equilibrium position relative to the body in the absence of the force.

3. The socket of claim 2, wherein the sleeve is universally pivotable about the point and wherein the at least one electrical contact is connected via a flexible conductor to a corresponding terminal extending outwardly from the body.

4. The socket of claim 2, wherein the sleeve is pivotable about an axis of rotation passing through the point and oriented orthogonally to the longitudinal axis of the sleeve and wherein the at least one conductor extends from a base of the body for connecting the socket to a printed circuit board.

5. The socket of claim 3, wherein the sleeve is in a form of a bore passing through a ball.

6. The socket of claim 5, wherein the body comprises formations for supporting the ball within the body for rotation relative to the body.

7. The socket of claim 6, wherein the bias comprises one of:
a spring member connected to the body and to the ball; and
a first magnet located in the body and a second magnet located in the ball.

8. The socket of claim 4, wherein the sleeve is in the form of a bore extending between diametrically opposed points on a circumferential edge of a disc.

9. The socket of claim 8, wherein the disc and the body comprise complementary formations for supporting the disc within the body for rotation about the axis of rotation.

10. The socket of claim 9, wherein the bias comprises one of:
a spring member connected to the body and to the disc; and
a first magnet located in the body and a second magnet located in the disc

11. The socket of claim 6, comprising a front face of the body with an aperture therein exposing an open end of the sleeve for receipt of the plug and wherein the aperture is dimensioned to limit movement of the sleeve when the plug inserted therein.

12. The socket of claim 11 wherein a portion of the ball protrudes from the front face of the body through the aperture.

13. The socket of claim 11, wherein a portion of the disc protrudes from the front face of the body through the aperture.

14. The socket of claim 11, wherein the front face of the body comprises a flanged rim surrounding the aperture.

15. The socket of claim 14, wherein the flanged rim is threaded for mounting the socket on a panel.

16. The socket of claim 15, wherein the body is of clam shell construction.

17. A printed circuit board comprising:
a plurality of electrical components including an electrical socket, located within the housing, the electrical socket comprising:
a body including a base;
a sleeve mounted in the body for receiving an electrical plug, wherein the sleeve has a longitudinal axis;
at least one electrical contact located in the sleeve for completing an electrical connection with a corresponding electrical contact of the electrical plug when inserted in the sleeve; wherein the sleeve is mounted to pivot about a point on the longitudinal axis thereof for movement relative to the body in response to a force applied to the sleeve in a direction lateral to the longitudinal axis of the sleeve and wherein the sleeve is pivotable about an axis of rotation passing through the point and oriented orthogonally to the longitudinal axis of the sleeve; and
at least one conductor, wherein the at least one conductor extends from the base of the body for connecting the socket to the printed circuit board.

18. A portable electronic device comprising:
a housing;
electronic circuitry located within the housing; and
an electrical socket, located within the housing, the electrical socket comprising:
a body;
a sleeve mounted in the body for receiving an electrical plug, wherein the sleeve has a longitudinal axis;
at least one electrical contact located in the sleeve for completing an electrical connection with a corresponding electrical contact of the electrical plug when inserted in the sleeve, wherein the sleeve is mounted to pivot about a point on the longitudinal axis thereof for movement relative to the body in response to a force applied to the sleeve in a direction lateral to the longitudinal axis of the sleeve; and
wherein the electrical socket is connected to the electronic circuitry to enable removable connection of the portable electronic device to an external electrical signal source via insertion of a plug.

19. The portable electrical device of claim 18, wherein the external signal source is an electrical power source and the socket is a power inlet socket connected to power supply components of the electronic circuitry.

20. The portable electrical device of claim 18 wherein the external signal source is an input signal source and the socket is a signal input socket connected to signal processing components of the electronic circuitry.
